(19) United States
(12) Patent Application Publication
(10) Pub. No.: US 2020/0245500 A1
(43) Pub. Date: Jul. 30, 2020

(54) EMBEDDED COOLING TUBES, SYSTEMS INCORPORATING THE SAME, AND METHODS OF FORMING THE SAME

(71) Applicant: TOYOTA MOTOR ENGINEERING & MANUFACTURING NORTH AMERICA, INC., Plano, TX (US)

(72) Inventors: Shailesh N. Joshi, Ann Arbor, MI (US); Naoya Take, Aichi (JP)

(73) Assignee: TOYOTA MOTOR ENGINEERING & MANUFACTURING NORTH AMERICA, INC., Plano, TX (US)

(21) Appl. No.: 16/256,599

(22) Filed: Jan. 24, 2019

(51) Int. Cl. H05K 7/20; H01L 23/367; H01L 23/473

(52) U.S. Cl. CPC H05K 7/20254; H01L 23/473; H01L 23/367

(57) ABSTRACT

The present disclosure generally relates to a stack including cooling tubes embedded within a solder, and methods of forming the same. A method of forming a stack includes placing a first amount of bond layer precursor material on a substrate, placing one or more cooling tubes on the first amount of bond layer precursor material, the one or more cooling tubes having a ceramic tube wall electroplated with a metal, placing a second amount of bond layer precursor material on the one or more cooling tubes such that the one or more cooling tubes are surrounded by bond layer precursor material placing an assembly having the one or more heat generating devices on the second amount of bond layer precursor material, and performing a bonding process to form a bond layer between the assembly and the substrate with the one or more cooling tubes disposed in the bond layer.

### BACKGROUND

### Field

The present specification generally relates to use of cooling tubes for heat transfer applications and, more particularly, to ceramic cooling tubes that are embedded in a bond layer between a substrate and a device to be cooled.

### Technical Background

Electronic devices may generally be coupled to cooling devices that remove heat generated by the electronic devices so as to minimize device damage, maintain or increase the efficiency of the functionality of the electronic device, and/or the like.

As electronic devices become more complex, the electronic devices tend to generate more heat. As excessive heat can be detrimental to the functionality of the electronic devices, it becomes necessary to develop cooling technologies that can effectively cool the electronic devices.

### SUMMARY

In one embodiment, a method of forming a stack having a cooling device thermally coupled to one or more heat generating devices includes placing a first amount of bond layer precursor material on a substrate, placing one or more cooling tubes on the first amount of bond layer precursor material, the one or more cooling tubes having a ceramic tube wall electroplated with a metal, placing a second amount of bond layer precursor material on the one or more cooling tubes such that the one or more cooling tubes are surrounded by bond layer precursor material, placing an assembly including the one or more heat generating devices on the second amount of bond layer precursor material, and performing a bonding process to form a bond layer between the assembly and the substrate with the one or more cooling tubes disposed in the bond layer.

In another embodiment, a cooling device that cools one or more heat generating devices in an assembly includes a substrate, a bond layer formed between the substrate and the assembly, the bond layer including solder or a transient liquid phase (TLP) alloy, and one or more cooling tubes embedded in the bond layer, the one or more cooling tubes having a ceramic tube wall electroplated with a metal.

In yet another embodiment, a stack includes an assembly having one or more heat generating devices, a substrate, a bond layer disposed between the assembly and the substrate, the bond layer including a solder or a transient liquid phase (TLP) alloy, and one or more cooling tubes disposed within the bond layer, the one or more cooling tubes including a ceramic tube wall electroplated with a metal.

These and additional features provided by the embodiments described herein will be more fully understood in view of the following detailed description, in conjunction with the drawings.

### BRIEF DESCRIPTION OF THE DRAWINGS

The embodiments set forth in the drawings are illustrative and exemplary in nature and not intended to limit the subject matter defined by the claims. The following detailed description of the illustrative embodiments can be understood when read in conjunction with the following drawings, wherein like structure is indicated with like reference numerals and in which:

FIG. 1 schematically depicts an illustrative stack including an electronic device coupled to a cooling device according to one or more embodiments shown and described herein;

FIG. 2A schematically depicts a cross-sectional view of the illustrative stack of FIG. 1 taken along line A-A;

FIG. 2B schematically depicts a cross-sectional view of another illustrative stack including a plurality of electronic devices coupled to a cooling device according to one or more embodiments shown and described herein;

FIG. 3 schematically depicts a perspective view of an illustrative cooling tube of a cooling device according to one or more embodiments shown and described herein;

FIG. 4A schematically depicts a cross-sectional view of the cooling tube of FIG. 3, taken along lines B-B;

FIG. 4B schematically depicts a cross-sectional view of the cooling tube of FIG. 3, taken along lines C-C; and

FIG. 5 depicts a flow diagram of an illustrative method of forming a stack including one or more heat generating devices and a cooling device according to one or more embodiments shown and described herein.

### DETAILED DESCRIPTION

The present disclosure relates generally to cooling devices for cooling heat generating devices, particularly cooling devices that utilize cooling tubes to direct fluid to a location adjacent to a heat generating device (e.g., an electronic device) to be cooled. The cooling tubes described herein are constructed of a ceramic material that is embedded within the bond layer that is typically present between the heat generating device and a collector, which allows the cooling tubes to be placed as close as possible to the heat generating device to more effectively transfer heat relative to cooling tubes placed in other locations. The present disclosure further relates to a particular method of electroplating the cooling tubes with a metal layer such that the tubes can be appropriately embedded within the bond layer.

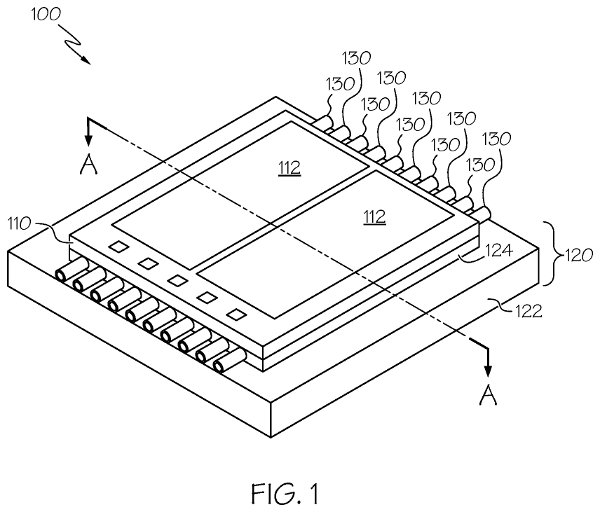

Referring now to the drawings, FIG. 1 depicts a stack, generally designated 100, according to various embodiments. The stack 100 may generally be a system including a cooling device 120 thermally coupled to an assembly 110 having one or more heat generating devices 112. The cooling device 120 generally includes at least a substrate 122 (e.g., a collector or the like) coupled to or integrated with one or more cooling tubes 130 that are embedded within a bond layer 124 between the assembly 110 including the one or more heat generating devices 112 and the substrate 122. That is, the one or more cooling tubes 130 are embedded within the bond layer 124 that bonds the assembly 110 containing one or more heat generating devices 112 to the substrate 122 so as to place the cooling tubes 130 as close as possible to the one or more heat generating devices 112 to maximize the amount and/or effectiveness of heat transfer of heat generated by the one or more heat generating devices 112. In some embodiments, the one or more cooling tubes 130 may be embedded within the bond layer 124 to maximize the heat transfer surface area of each of the one or more cooling tubes 130. As such, the one or more cooling tubes 130 are generally positioned to contact the one or more heat generating devices 112 to draw heat flux from the one or more heat generating devices 112. Thus, as the one or more heat generating devices 112 generate heat, the heat is drawn away from the one or more heat generating devices 112 via the one or more cooling tubes 130.

The assembly 110 is not limited by the present disclosure and may generally be any device that supports or contains the one or more heat generating devices 112. In some embodiments, the assembly 110 may be a substrate. For example, the assembly 110 may be a chip in some embodiments.

The one or more heat generating devices 112 are not limited by the present disclosure, and may each generally be any device that generates heat as a byproduct of operation. For example, in some embodiments, the one or more heat generating devices 112 may include an emitter electrode coupled to the chip (the assembly 110). In another example, the one or more heat generating devices 112 may be any heat emitting semiconductor device. In some embodiments, the one or more heat generating devices 112 may be shaped and/or sized so as to necessitate sub-millimeter sized cooling tubes 130, as described herein. That is, the one or more heat generating devices 112 may be a shape and/or a size such that cooling tubes 130 that are greater than about 1 mm in outside diameter may be ineffective in drawing heat away from the one or more heat generating devices 112, thereby necessitating sub-millimeter sized cooling tubes 130 to effectively draw heat away from the one or more heat generating devices 112. In some embodiments, the one or more heat generating devices 112 may each be a semiconductor device such as, for example, an insulated-gate bipolar transistor (IGBT), a diode, a transistor, an integrated circuit, a silicon-controlled rectifier (SCR), a thyristor, a gate turn-off thyristor (GTO), a triac, a bipolar junction transistor (BJT), a power metal oxide semiconductor field-effect transistor (MOSFET), a MOS-controlled thyristor (MCT), an integrated gate-commutated thyristor (IGCT), or the like. In a particular embodiment, the one or more heat generating devices 112 may include a wide bandgap semiconductor device. Other examples of the one or more heat generating devices 112 not specifically described herein should generally be understood, and are included within the scope of the present disclosure.

The cooling device 120 may generally be any device or system that cools via heat transfer, particularly devices or systems that direct a cooling fluid to, from, and/or via the one or more cooling tubes 130. Illustrative examples of devices or systems that cool via heat transfer (e.g., via heat exchange) include, but are not limited to, pool boiling units, heat pipe assemblies, heat spreaders, vapor chambers, thermoelectric cooling devices, thermal diodes, and other heat exchange devices not specifically described herein. The devices and systems may generally incorporate and/or may be fluidly coupled to the one or more cooling tubes 130 to direct cooling fluid into the one or more cooling tubes 130 and/or to remove heated cooling fluid from the one or more cooling tubes 130. As such, the cooling tubes 130 may be fluidly coupled to one or more additional components (not shown) for the purposes of directing fluid therethrough.

In some embodiments, the cooling device 120 may be an active heat management device. That is, the cooling device 120 actively draws heat from the one or more heat generating devices 112 by flowing a cooling fluid through the one or more cooling tubes 130. However, the cooling device 120 may be a passive heat management device in other embodiments. That is, the cooling device 120 (and particularly the cooling tubes 130 therein) may act as devices that are particularly configured to dissipate the heat generated by the one or more heat generating devices 112 by providing an increased surface area for heat dissipation. As active and passive heat management are generally understood, such details are not described further herein.

The one or more cooling tubes 130 may generally be any tubes that allow fluid flow therethrough. The length of the one or more cooling tubes 130 is not limited by the present disclosure, and may generally be any length. In the embodiment depicted in FIG. 1, the cooling tubes 130 generally have the same length. However, the present disclosure is not limited to such. That is, each of the cooling tubes 130 may have a different length relative to other ones of the cooling tubes 130 in some embodiments. Also in the embodiment depicted in FIG. 1 are ten (10) cooling tubes 130. However, the present disclosure is not limited to such. That is, the number of cooling tubes 130 may be greater than or less than ten cooling tubes 130. In addition, the arrangement and configuration of the cooling tubes 130 as depicted in FIG. 1 (e.g., generally aligned and coplanar with one another) is also merely illustrative, and other arrangements and configurations are contemplated. The cooling tubes 130 may be straight tubes in some embodiments (as depicted in FIG. 1 for example) or may be bent, angled, or otherwise curved without departing from the scope of the present disclosure. While the term “tube” is generally understood to be a cylindrical object having a circular or oval cross-section, the present disclosure is not limited to such. That is, each of the one or more cooling tubes 140 may have a cross-sectional shape that is any regular or irregular shape.

The cooling tubes 130 may be formed from any ceramic material, particularly ceramic materials exhibiting a high thermal conductivity. That is, the cooling tubes 130 may generally be formed from ceramic materials that are generally understood to be used for thermal conduction. In addition, the cooling tubes may be coated with a metal coating, as described in greater detail herein. In some embodiments, the cooling tubes 130 may adhere to certain standards, such as, for example, ASTM B280 and ASTM B360 standards. The cooling tubes 130 may generally be any yet-to-be-developed or commercially available tubes, such as, without limitation, tubes available from CeramTec (Plochingen, Germany).

In some embodiments, the cooling tubes 130 may have a sub-millimeter outside diameter. That is, the cooling tubes 130 described herein may generally have a diameter that is less than about 1 millimeter (mm) when measured from points along an outside surface. For example, the outside diameter of each of the cooling tubes 130 may be about 0.9 mm, about 0.8 mm, about 0.7 mm, about 0.6 mm, about 0.5 mm, about 0.4 mm, about 0.3 mm, about 0.2 mm, about 0.1 mm, smaller than 0.1 mm, or any value or range between any two of these values (including endpoints). In some embodiments, each of the cooling tubes 130 may have a uniform outside diameter. In other embodiments, the cooling tubes 130 may have varying outside diameters. While sub-millimeter outside diameter cooling tubes 130 are generally discussed herein, the present disclosure is not limited to such. That is, the cooling tubes 130 may have an outside diameter that is greater than about 1 mm in some embodiments.

The substrate 122 of the cooling device 120 is not limited by the present disclosure, and may generally be any substrate, particularly substrates that are adapted to support the various components of the stack 100 (e.g., the cooling tubes 130 embedded in the bond layer 124, the assembly 110 containing the one or more heat generating devices 112, and/or the like). For example, the substrate 122 may be constructed of a thermally conductive material. Substrates that are used for heat exchange devices should be generally understood, particularly those that are formed of a thermally conductive material, and are not described in further detail herein. The substrate 122 may be any shape or size, and is not limited by the present disclosure. In some embodiments, the substrate 122 may be shaped and/or sized to correspond to a shape and/or size of the assembly 110 and/or the one or more heat generating devices 112. In the embodiment depicted in FIG. 1, the substrate 122 may be sized such that it is generally larger than the assembly 110 containing the one or more heat generating devices 121 (e.g., the substrate 122 has a footprint that is larger than the footprint of the assembly 110). In some embodiments, the substrate 122 may be shaped, sized, and configured to support a single heat generating device 112 thereon. In other embodiments, the substrate 122 may be shaped, sized, and configured to support a plurality of heat generating devices 112 thereon. In some embodiments, the substrate 122 may be a collector for an IGBT.

The bond layer 124 may be a solder or a bonding material (e.g., a transient liquid phase (TLP) bonding material such as an alloy of a low melting temperature material (e.g., tin or indium) and a high melting temperature material (e.g., copper, nickel, or aluminum)) that is dispersed between the substrate 122 and the assembly 110 (with the one or more cooling tubes 130 embedded therein) to secure the various components of the stack 100 together.

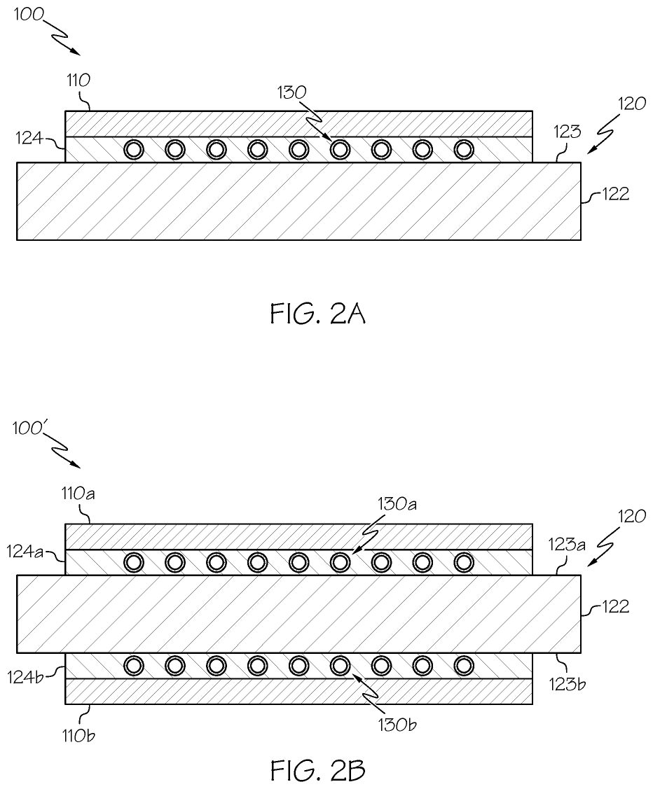

FIG. 2A depicts a cross-sectional view of the stack 100 taken along line A-A according to various embodiments. As shown in FIG. 2A, the substrate 122 of the cooling device 120 in the stack 100 is bonded to the assembly 110 via the bond layer 124 with the one or more cooling tubes 130 embedded therein. That is, a first major surface 123 (e.g., an upper surface) of the substrate 122 that faces the cooling device 120 may be at least partially covered with the bond layer 124 with the cooling tubes 130 embedded therein.

Each of the one or more cooling tubes 130 may generally be positioned within the bond layer 124 to effect heat transfer, as described herein. In some embodiments, the one or more cooling tubes 130 may have a patterned surface (e.g., an interior patterned surface and/or an exterior patterned surface) to maximize surface area for heat transfer. That is, the surface area of the interior and/or the exterior of each of the cooling tubes 130 may be increased via any patterning process or other process that increases surface area, as it is generally understood that increased surface area increases heat transfer.

While the stack 100 may only include a single assembly 110 coupled to a single cooling device 120 (as depicted in FIG. 2A), the stack 100 may also have other configurations in other embodiments. For example, as depicted in FIG. 2B, an alternative stack 100′ may include the cooling device 120 comprising a single substrate 122 having a first major surface 123a (e.g., an upper surface) and a second major surface 123b (e.g., a lower surface) opposite the first major surface 123a. A first assembly 110a may be bonded to the first major surface 123a of the substrate 122 via a first bond layer 124a having one or more first cooling tubes 130a embedded therein. A second assembly 110b may be bonded to the second major surface 123b of the substrate 122 via a second bond layer 124b having one or more second cooling tubes 130 embedded therein.

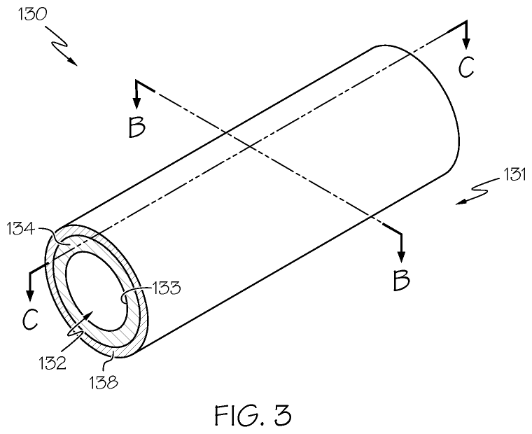

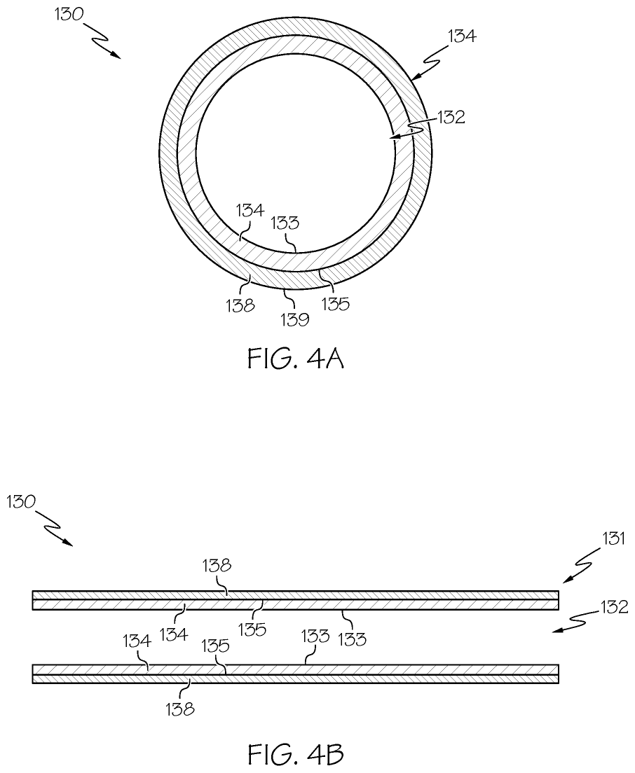

As generally depicted in FIGS. 2A and 2B and shown in greater detail in FIGS. 3, 4A and 4B, each of the one or more cooling tubes 130 is hollow such that a hollow interior 132 of the cooling tube 130 allows a fluid (e.g., a cooling fluid) to pass therethrough. That is, the cooling tube 130 includes a tube wall 134 having an interior surface 133 and an exterior surface 135, the tube wall 134 defining the hollow interior 132 of the cooling tube 130. The tube wall 134 and the hollow interior 132 are not limited in dimensional characteristics by this disclosure. That is, the tube wall 134 may have any shape, size, and thickness and the hollow interior 132 defined by the tube wall 134 may also be any shape or size that maintains a space therein for fluid flow, as described in greater detail herein.

In some embodiments, the tube wall 134 of the cooling tube 130 may be particularly configured for the purposes of active cooling, as described herein. That is, the cooling tube 130 is used to flow a cooling fluid therethrough to draw latent heat away from the one or more heat generating devices 112 (FIG. 1). Still referring to FIGS. 3 and 4A-4B, in other embodiments, the tube wall 134 in the cooling tube 130 may be particularly configured for the purposes of passive cooling. That is, the tube wall 134 may be patterned or otherwise function similar to that of a finned surface or the like to dissipate heat in a passive manner (e.g., acts as a heat spreader), as is generally understood. As such, in some embodiments, the hollow interior 132 of the cooling tube 130 may have a patterned structure thereon that is particularly formed to maximize an amount of surface area on the interior of the cooling tube 130 to increase heat transfer. In some embodiments, the patterned structure may be any sintered structure, inverse opal structure, or the like.

As previously described herein, the tube wall 134 may generally be constructed of a thermally conductive ceramic material, but is otherwise not limited by the present disclosure. In some embodiments, the material used for the tube wall 134 may be selected based on a process used to form the tube wall 134, the size of the tube wall 134, electrical isolation properties, and/or the like. Illustrative ceramics include, but are not limited to, beryllium oxide, aluminum nitride, boron nitride, alumina, composites of any of the foregoing, and/or the like. Other ceramic materials that are not specifically disclosed herein are also included within the scope of the present disclosure.

It should be understood that the inherent properties of the ceramic used for the tube wall 134 may be electrically insulative. However, in some embodiments, the interior surface 133 of the tube wall 134 may be at least partially coated with an additional electrical insulator material that further electrically insulates the tube wall 134 from other components that would otherwise contact the tube wall 134. For example, the interior surface 133 of the tube wall 134 may be electrically insulated from the cooling fluid that is passed through the cooling tubes 130 during operation, so as to avoid instances where the cooling fluid corrodes or otherwise causes damage to various components of the stack 100 (FIG. 1). Illustrative examples of the electrical insulator material that may be formed on the interior surface 133 of the tube wall 134 may include, but are not limited to, alumina and silicon dioxide (SiO₂). The insulator material may be formed on the interior surface 133 of the tube wall 134 via any deposition method now known or later developed, particularly deposition methods that are suited for the materials used. In some embodiments, the insulator material may be deposited on the interior of the tube wall 134 via atomic layer deposition (ALD) or chemical vapor deposition (CVD) processes.

It should generally be understood that the ceramic material used for the tube wall 134 may not effectively bind to the material used in the bond layer 124 depicted in FIG. 2 (e.g., solder material, TLP intermetallic compound layers, or the like). As such, the exterior surface 135 of the tube wall 134 may be coated or otherwise covered with one or more additional materials to ensure proper bonding to the bond layer 124 (FIG. 2). Still referring to FIGS. 3 and 4A-4B, the tube wall 134 may be coated or otherwise covered with a coating 138. In some embodiments, the coating 138 may cover the entire exterior surface 135 of the tube wall 134. In other embodiments, the coating 138 may only cover a portion of the exterior surface 135 of the tube wall 134. To cover the tube wall 134 with the coating 138, the tube wall 134 may be placed in an electrolyte solution containing dissolved metal salts (e.g., metal salts containing copper, nickel, silver, gold, and/or the like) and/or an acidic solution that also contains a solid metal placed therein, to effect an electroplating process, as described in greater detail herein. The coating 138 includes a contact surface 131 that can be contacted with the material used for the bond layer 124 to fix the cooling tube 130 within the bond layer 124, as described in greater detail herein.

The coating 138 may generally be any material that can be electroplated onto a ceramic and generally exhibits adhesive properties with a material used in the bond layer 124 (FIG. 2) such as, but not limited to, a metal, a metal alloy, and/or the like. Nonlimiting examples of materials that may be used for the coating 138 include copper (Cu), nickel (Ni), silver (Ag), gold (Au), alloys containing one or more of the foregoing, and/or the like.

Referring collectively to FIGS. 1, 2A-2B, 3, and 4A-4B, it should now be understood that the stack 100 includes the assembly 110 containing one or more heat generating devices 112 thermally coupled to a cooling device 120 that includes at least a substrate 122 and the one or more cooling tubes 130. The assembly 110 is bonded to the substrate 122 via the bond layer 124 with the one or more cooling tubes 130 embedded therein so as to place the one or more cooling tubes 130 as close as possible to the one or more heat generating devices 112 for effective heat transfer. Due to the inherent inability to bond the ceramic materials used for the one or more cooling tubes 130 with the materials used for the bond layer 124, the tube wall 134 of each of the one or more cooling tubes 130 is coated with a coating 138 so that the one or more cooling tubes 130 can be effectively fixed within the bond layer 124 between the assembly 110 and the substrate 122.

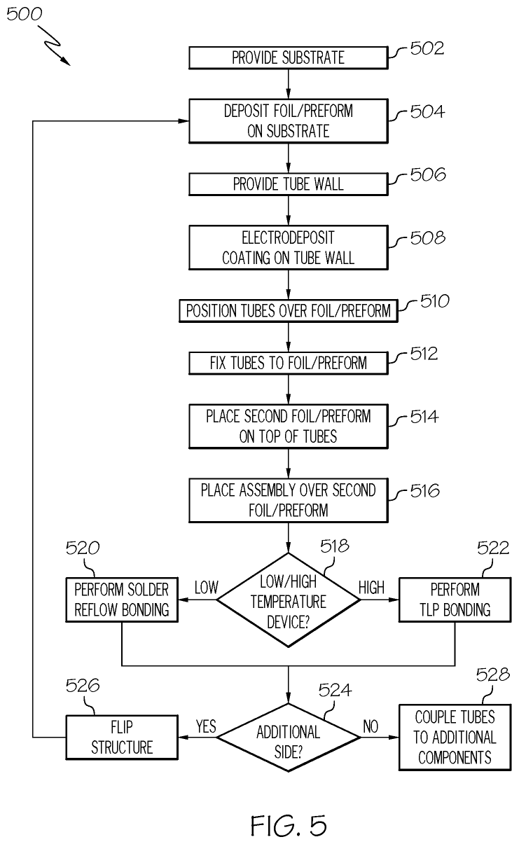

A method used to form the stack 100 is depicted in FIG. 5. Referring collectively to FIGS. 1-5, the substrate 122 may be provided at block 502. At block 504, a foil or preform may be deposited on the substrate 122. The foil or preform is a first amount of a precursor material that is used to form the bond layer 124. For example, the foil or preform is used to form solder during a reflow process or form a TLP bond during a TLP bonding process, as described herein. Nonlimiting examples of foil or preform materials include tin, indium, copper, nickel, aluminum, alloys of one or more of the foregoing, compounds including one or more of the foregoing, and/or the like. While the present disclosure specifically relates to foils or preforms, it should be understood that other material forms that are used to form solder or a TLP bond, such as powders, pastes (e.g., a combination of powdered solder and flux), core/shell materials, and/or the like, can also be used without departing from the scope of the present disclosure.

At blocks 506-508, the cooling tubes 130 are prepared. That is, for each of the cooling tubes 130 to be used, the processes described with respect to blocks 506-508 may be completed. More specifically, at block 506, the tube wall 134 is provided and the coating 138 is electrodeposited thereon at block 508 for each of the one or more cooling tubes 130. As is generally understood, the tube wall 134 may be placed in an electrolyte solution containing dissolved metal salts (e.g., metal salts containing copper, nickel, silver, gold, and/or the like) and/or an acidic solution that also contains a solid metal placed therein. For example, the tube wall 134 and a solid copper rod may be placed in an acidic bath, such as a copper sulfate bath. An electrical source is coupled to the tube wall 134 and the solution (or the solid metal) such that the tube wall 134 acts as a cathode and the solution (or the solid metal) acts as an anode. Following the example provided above, the tube wall 134 may be electrically coupled to a negative terminal of a power source and the solid copper rod may be electrically coupled to a positive terminal of the power source. Accordingly, a current is applied to the solution (or to the solid metal placed in the solution), which causes the metal ions in the metal salts to plate out onto the tube wall 134 and form the coating 138 on the tube wall 134. In some embodiments, the interior surface 133 of the tube wall 134 may be plugged or otherwise isolated prior to placement in the bath such that the electrodeposition process does not result in the coating 138 being applied to the interior surface 133. Rather, only the exterior surface 135 of the tube wall 134 includes the coating 138 thereon.

At block 510, the cooling tubes 130 are positioned over the foil or preform material on the substrate 122. That is, the cooling tubes 130 in any number or configuration as desired to effect heat transfer. In some embodiments, the cooling tubes 130 may be spaced apart and parallel to one another, as depicted in FIG. 1. However, it should be understood that the cooling tubes 130 may be placed in any other configuration without departing from the scope of the present disclosure. For example, the cooling tubes 130 may be placed in a grid configuration, in a spiral configuration, and/or the like.

Still referring collectively to FIGS. 1-5, in order to ensure that the cooling tubes 130 remain fixed in a particular position during the bonding process (including a solder reflow process and a TLP bonding process), the cooling tubes 130 may be fixed to the foil or preform using a fixture at block 512. For example, a solid piece of graphite or the like may be placed around the tubes to fix the cooling tubes 130 in place during the bonding or soldering process, as described in greater detail herein. It should generally be understood that the carbon atoms in graphite may assist in the process of bonding the coating 138 to the material used for the bond layer 124 (e.g., a eutectic bonding process).

At block 514, a second or subsequent foil or preform may be placed over the cooling tubes 130. That is, another layer of a precursor material that is used to form the bond layer 124 is placed over the cooling tubes 130. The second foil or preform may be the same material as the foil or preform that is placed according to block 504, or may be a different type of material as the foil or preform that is placed according to block 504. Nonlimiting examples of foil or preform materials that can be used for the second foil or preform include tin, indium, copper, nickel, aluminum, alloys of one or more of the foregoing, compounds including one or more of the foregoing, and/or the like. While the present disclosure specifically relates to foils or preforms for the second foil or preform, it should be understood that other material forms that are used to form solder or a TLP bond, such as powders, pastes (e.g., a combination of powdered solder and flux), core/shell materials, and/or the like, can also be used without departing from the scope of the present disclosure.

At block 516, the assembly 110 (including the one or more heat generating devices 112) may be placed over the second foil or preform. At block 518, a determination may be made as to what type of bonding process is used, which may be determined based on whether the one or more heat generating devices 112 are relatively high temperature devices or relatively low temperature devices. A relatively high temperature device may be, for example, a device that has an operating temperature of about 200° C. or greater than 200° C. An illustrative device that may have a relatively high operating temperature includes, but is not limited to, a wide bandgap semiconductor devices. A relatively low temperature device may be, for example, less than about 200° C. If the one or more heat generating devices 112 operate at a relatively low operating temperature (e.g., less than about 200° C.), the process may proceed to block 520. If the one or more heat generating devices 112 operate at a relatively high operating temperature (e.g., greater than or equal to about 200° C.), the process may proceed to block 522. It should be understood that the decision at block 518 as to which bonding process to utilize may be based on other factors other than operating temperature (e.g., cost, types of materials available, bond characteristics, etc.). As such, the present disclosure is not limited to a determination based solely on temperature.

At block 520, a solder reflow bonding process may be completed to bond the substrate 122 to the assembly 110 with the one or more cooling tubes 130 embedded in the bond layer 124 therebetween. The stack 100 may be placed in a reflow oven, subjected to a heat lamp, and/or the like to cause the reflow process and bind the components together. As the solder reflow process is generally understood, such a process is not described in greater detail herein.

At block 522, a TLP bonding process may be performed. For example, for a TLP bonding process, at least a portion of the cooling tubes 130 may be fixed between the substrate 122 and the assembly 110 by providing a low melting temperature material (e.g., tin or indium) as one of the foil or preform materials described herein adjacent to a high melting temperature material (e.g., copper, nickel, or aluminum) as the other one of the foil or preform materials as described herein. For example, the foil or preform placed on the substrate 122 according to block 504 may be the low melting temperature material and the second foil or preform placed on the one or more cooling tubes 130 according to block 514 may be the high melting temperature material, or vice versa. In other embodiments, the low melting temperature material and the high melting temperature material may be provided via individual particles or core/shell particles including the low and high melting temperature materials that are dispersed around the one or more cooling tubes 130. The low melting temperature material has a lower melting temperature than the high melting temperature material. During TLP bonding, the cooling tubes 130, the low and high melting temperature materials, the assembly 110, and the substrate 122 are subjected to a sintering temperature greater than the melting temperature of the low melting temperature material (e.g., between about 280° C. and about 350° C.) for a period of time. The sintering temperature causes the low melting temperature material to melt and diffuse into the high melting temperature material, thereby forming one or more intermetallic compound layers that bond the substrate 122 to the assembly 110 with the cooling tubes 130 embedded therebetween. The one or more intermetallic compound layers (i.e., TLP bond layers) have a melting temperature that is greater than the sintering temperature.

Regardless of the type of bonding process (e.g., solder reflow according to block 520 or TLP bonding according to block 522), the process may continue at block 524. At block 524, a determination is made as to whether an additional side of the substrate 122 is to receive an assembly 110. That is, a determination is made as to whether the stack 100 as depicted in FIG. 2A (e.g., a single assembly 110 bonded to a single side of the substrate 122) is used or needed, the stack 100′ as depicted in FIG. 2B (e.g., first and second assemblies 110a, 110b bonded to either side of the substrate 122) and additional sides are to have an assembly 110 added thereto are used or needed, or a stack having more than two assemblies with additional sides to be added is used or desired. If an additional side of the substrate 122 is to be added, the process may proceed to block 526. If an additional side of the substrate 122 is not to be added (either because another side has already been added or no additional sides are used/desired), the process may proceed to block 528.

At block 526, the structure may be flipped, rotated, or otherwise moved for a new application of the assembly 110 and the one or more cooling tubes 130 on another surface thereof. Accordingly, the process may return to block 504. If no additional assemblies are needed or used, the one or more cooling tubes 130 may be coupled to additional components at block 528 in some embodiments. That is, the one or more cooling tubes 130 may be coupled to other components of the cooling device 120 (FIG. 1) to form the remainder of the cooling device 120, as described herein. For example, the one or more cooling tubes 130 may be fluidly coupled to a fluid source and/or a fluid destination such that cooling fluid may be flowed through the cooling tubes 130, as described herein.

The processes described with respect to FIG. 5 are merely illustrative, and other processes may be used in the alternative. In addition, the specific processes described with respect to FIG. 5 may be substituted with other processes and/or supplemented with other processes. In some embodiments, particular processes described with respect to FIG. 5 may be omitted or combined with other processes. In some embodiments, the various processes may be completed in a different order. For example, the processes described with respect to blocks 506-508 (relating to preparation of the cooling tubes 130) may be completed separately from the remaining processes described in FIG. 5, and may occur at substantially the same time as the processes described with respect to blocks 502 and 504 or prior to the processes described with respect to blocks 502 and 504 (e.g., cooling tubes 130 may be pre-prepared prior to assembly of the stack 100).

It should now be understood that the present disclosure relates to cooling devices that utilize cooling tubes to direct fluid to a location adjacent to a heat generating device (e.g., an electronic device) to be cooled. The cooling tubes are constructed of a ceramic material electroplated with a metal that is embedded within the bond layer that is typically present between the heat generating device and a collector, thereby placing the cooling tubes as close as possible to the heat generating device to more effectively transfer heat relative to cooling tubes placed in other locations/arranged in other configurations.

While particular embodiments have been illustrated and described herein, it should be understood that various other changes and modifications may be made without departing from the spirit and scope of the claimed subject matter. Moreover, although various aspects of the claimed subject matter have been described herein, such aspects need not be utilized in combination. It is therefore intended that the appended claims cover all such changes and modifications that are within the scope of the claimed subject matter.

What is claimed is:

1. A method of forming a stack comprising a cooling device thermally coupled to one or more heat generating devices, the method comprising:
placing a first amount of bond layer precursor material on a substrate;
placing one or more cooling tubes on the first amount of bond layer precursor material, wherein the one or more cooling tubes comprise a ceramic tube wall electroplated with a metal;
placing a second amount of bond layer precursor material on the one or more cooling tubes such that the one or more cooling tubes are surrounded by bond layer precursor material;
placing an assembly comprising the one or more heat generating devices on the second amount of bond layer precursor material; and
performing a bonding process to form a bond layer between the assembly and the substrate with the one or more cooling tubes disposed in the bond layer.

2. The method of claim 1, wherein performing the bonding process comprises performing solder reflow bonding or performing transient liquid phase (TLP) bonding.

3. The method of claim 1, further comprising:
placing a third amount of bond layer precursor material on a second surface of the substrate;
placing a second one or more cooling tubes on the third amount of bond layer precursor material, wherein the second one or more cooling tubes comprise a ceramic tube wall electroplated with a metal;
placing a fourth amount of bond layer precursor material on the second one or more cooling tubes such that the second one or more cooling tubes are surrounded by bond layer precursor material;
placing a second assembly comprising the one or more heat generating devices on the fourth amount of bond layer precursor material; and
performing a second bonding process to form a second bond layer between the second assembly and the substrate with the second one or more cooling tubes disposed in the second bond layer.

4. The method of claim 1, wherein:
placing the first amount of bond layer precursor material comprises placing a first material having a first melting temperature; and
placing the second amount of bond layer precursor material comprises placing a second material having a second melting temperature.

5. The method of claim 4, wherein the first melting temperature is less than the second melting temperature.

6. The method of claim 4, wherein the first melting temperature is greater than the second melting temperature.

7. The method of claim 4, wherein:
the first material is tin or indium; and
the second material is copper, nickel, or aluminum.

8. The method of claim 1, further comprising fixing the one or more cooling tubes to the first amount of bond layer precursor material prior to placing the second amount of bond layer precursor material.

9. The method of claim 1, further comprising forming the one or more cooling tubes, wherein forming the one or more cooling tubes comprises:
providing the ceramic tube wall formed from beryllium oxide, aluminum nitride, boron nitride, alumina, or composites of any of the foregoing; and
electrodepositing the metal on the ceramic tube wall, the metal selected from copper, nickel , silver, gold, and an alloy containing one or more of the foregoing.

10. A cooling device that cools one or more heat generating devices in an assembly, the cooling device comprising:
a substrate;
a bond layer formed between the substrate and the assembly, the bond layer comprising solder or a transient liquid phase (TLP) alloy; and
one or more cooling tubes embedded in the bond layer, the one or more cooling tubes comprising a ceramic tube wall electroplated with a metal.

11. The cooling device of claim 10, wherein the metal is copper, nickel, silver, gold, or an alloy containing one or more of the foregoing.

12. The cooling device of claim 10, wherein the one or more cooling tubes are adapted to receive a cooling fluid within a hollow interior thereof such that the cooling fluid receives latent heat transferred from the one or more heat generating devices to the one or more cooling tubes.

13. The cooling device of claim 10, wherein the cooling device is an active cooling device.

14. The cooling device of claim 10, wherein the cooling device is a passive cooling device.

15. A stack comprising:
an assembly comprising one or more heat generating devices;
a substrate;
a bond layer disposed between the assembly and the substrate, the bond layer comprising a solder or a transient liquid phase (TLP) alloy; and
one or more cooling tubes disposed within the bond layer, the one or more cooling tubes comprising a ceramic tube wall electroplated with a metal.

16. The stack of claim 15, wherein the metal is copper, nickel, silver, gold, or an alloy containing one or more of the foregoing.

17. The stack of claim 15, wherein the one or more cooling tubes are adapted to receive a cooling fluid within a hollow interior thereof such that the cooling fluid receives latent heat transferred from the one or more heat generating devices to the one or more cooling tubes.

18. The stack of claim 15, wherein the one or more heat generating devices are wide bandgap semiconductor devices.

19. The stack of claim 15, wherein each of the one or more heat generating devices is an insulated-gate bipolar transistor (IGBT), a diode, a transistor, an integrated circuit, a silicon-controlled rectifier (SCR), a thyristor, a gate turn-off thyristor (GTO), a triac, a bipolar junction transistor (BJT), a power metal oxide semiconductor field-effect transistor (MOSFET), a MOS-controlled thyristor (MCT), or an integrated gate-commutated thyristor (IGCT).

20. The stack of claim 15, further comprising:
a second assembly comprising a second one or more heat generating devices;
a second bond layer disposed between the second assembly and a second surface of the substrate, the second bond layer comprising a solder or a TLP alloy; and
one or more second cooling tubes disposed within the second bond layer, the one or more second cooling tubes comprising a ceramic tube wall electroplated with a metal.
